(19) United States
(12) Patent Application Publication
(10) Pub. No.: US 2022/0187551 A1
(43) Pub. Date: Jun. 16, 2022

(54) OPTICAL RECEPTACLE, OPTICAL MODULE, AND METHOD FOR MANUFACTURING OPTICAL MODULE

(71) Applicant: Enplas Corporation, Saitama (JP)

(72) Inventors: Shimpei MORIOKA, Saitama (JP); Ayano KON, Saitama (JP)

(21) Appl. No.: 17/442,575

(22) PCT Filed: Mar. 26, 2020
(86) PCT No.: PCT/JP2020/013511

§ 371 Date: Sep. 23, 2021

(30) Foreign Application Priority Data
Mar. 26, 2019 (JP) 2019-059240

(51) Int. Cl. G02B 6/42

(52) U.S. Cl. CPC G02B 6/4246

(57) ABSTRACT

Provided is an optical receptacle capable of maintaining high optical coupling efficiency even when an optical transmission body having a large core end surface is used. An optical receptacle according to the present invention has: an optical receptacle body; and a filter. The optical receptacle body includes a first optical surface; a second optical surface; a third optical surface; and a reflection surface. The filter includes a first filter surface for reflecting light of a first wavelength while transmitting light of a second wavelength, and a second filter surface for reflecting the light of the second wavelength while transmitting the light of the first wavelength. The filter is disposed on the optical receptacle body so that the first filter surface or the second filter surface is closely attached to the reflection surface.

### TECHNICAL FIELD

The present invention relates to an optical receptacle, an optical module, and a method of manufacturing the optical module.

### BACKGROUND ART

In the related art, an optical module (optical transmission module) including a light-emitting element such as a light-emitting diode and a light-receiving element such as a photodetector is used for optical communications using an optical transmission member such as an optical fiber and a light waveguide. The optical module includes an optical receptacle (optical member) that allows, to enter the end surface of an optical transmission member, light containing communication information emitted from the light-emitting element, and allows, to enter the light-receiving surface of the light-receiving element, light containing communication information emitted from the optical transmission member (see, for example, PTL 1).

PTL 1 describes an optical element assembly including a transmitting optical element and a receiving optical element, an optical fiber, and an optical transmission module including an optical member. The optical member allows, to enter the optical fiber, an optical signal from the transmitting optical element, or allows, to enter the receiving optical element, an optical signal from the optical fiber. The optical member includes a transmitting lens disposed facing the transmitting optical element, a lens for fiber disposed facing the optical fiber, a receiving lens disposed facing the receiving optical element, an optical filter that reflects, toward the lens for fiber, the signal light entered from transmitting lens, or transmits the reception light entered from the lens for fiber, and a reflection surface that reflects, toward the receiving lens, the reception light transmitted through the optical filter. The optical filter is disposed facing the filter mounting surface of the filter mounting part, and is fixed to occupy the filter mounting part with a transparent adhesive agent.

### CITATION LIST

### Patent Literature

PTL 1
Japanese Patent Application Laid-Open No. 2009-251375

### SUMMARY OF INVENTION

### Technical Problem

In the optical element assembly disclosed in PTL 1, however, the filter mounting part for mounting the optical filter and the reflection surface disposed at a position separated from the filter mounting part are required to be provided in the optical member, and consequently the optical path between the optical fiber and the receiving optical element is lengthened, thus resulting in a large size of the optical transmission module. In addition, for example, in the case where an optical fiber with a large diameter of the end surface of the core is used, the lens for fiber may fail to perform complete conversion to collimated light. When the conversion of reception light into collimated light cannot be performed and the optical path between the optical fiber and the receiving optical element is long, the light coupling efficiency between the end surface of the optical fiber and the light-receiving surface of the receiving optical element is significantly degraded.

An object of the present invention is to provide an optical receptacle and an optical module that can maintain a high light coupling efficiency even in the case where the optical transmission member with a large core end surface is used.

### Solution to Problem

An optical receptacle according to an embodiment of the present invention is configured to optically couple an optical transmission member, a light-emitting element and a light-receiving element when the optical receptacle is disposed between the optical transmission member and a photoelectric conversion device including the light-emitting element and the light-receiving element, the optical transmission member being configured to emit light of a first wavelength, the light-emitting element being configured to emit light of a second wavelength different from the first wavelength, the light-receiving element being configured to receive the light of the first wavelength, the optical receptacle including: an optical receptacle main body; and a filter disposed on the optical receptacle main body, The optical receptacle main body includes: a first optical surface configured to allow incidence of the light of the first wavelength emitted from the optical transmission member, or emit, toward the optical transmission member, the light of the second wavelength having travelled inside the optical receptacle main body, a second optical surface configured to emit, toward the light-receiving element, the light of the first wavelength having travelled inside the optical receptacle main body, or allow incidence of the light of the second wavelength emitted from the light-emitting element, a third optical surface disposed at a position separated from the first optical surface than the second optical surface, and configured to emit, toward the light-receiving element, the light of the first wavelength having travelled inside the optical receptacle main body, or allow incidence of the light of the second wavelength emitted from the light-emitting element, and a reflection surface disposed on an optical path between the first optical surface and the second optical surface, and configured to internally reflect, toward the first optical surface, the light of the second wavelength entered from the second optical surface, or internally reflect, toward the second optical surface, the light of the first wavelength entered from the first optical surface, The filter includes: a first filter surface disposed at one surface and configured to reflect the light of the first wavelength and transmit the light of the second wavelength, and a second filter surface disposed at another surface and configured to reflect the light of the second wavelength and transmit the light of the first wavelength, When the second optical surface is used to emit the light of the first wavelength toward the light-receiving element, or when the third optical surface is used to allow incidence of the light of the second wavelength, the filter is disposed on the optical receptacle main body such that the first filter surface is in intimate contact with the reflection surface, the second filter surface reflects, toward the first optical surface, the light of the second wavelength entered from the third optical surface, and the reflection surface and the first filter surface reflect, toward the second optical surface, the light of the first wavelength entered from the first optical surface, or transmit, toward the first optical surface, the light of the second wavelength reflected by the second filter surface, and When the second optical surface is used to allow incidence of the light of the second wavelength, or when the third optical surface is used to emit, toward the light-receiving element, the light of the first wavelength, the filter is disposed on the optical receptacle main body such that the second filter surface is in intimate contact with the reflection surface, the reflection surface and the second filter surface reflect, toward the first optical surface, the light of the second wavelength entered from the second optical surface, or transmit, toward the first filter surface, the light of the first wavelength entered from the first optical surface, and the first filter surface reflects, toward the third optical surface, the light of the first wavelength transmitted through the second filter surface.

An optical module according to an embodiment of the present invention includes: a photoelectric conversion device including a substrate, a light-emitting element disposed on the substrate and a light-receiving element disposed on the substrate; and the above-described optical receptacle.

A method according to an embodiment of the present invention is a method of manufacturing the optical module, the method including: disposing the filter on the optical receptacle main body such that the first filter surface is in intimate contact with the reflection surface when the size of the end surface of the core of the optical transmission member is equal to or greater than the size of the light-emitting surface of the light-emitting element, or disposing the filter on the optical receptacle main body such that the second filter surface is in intimate contact with the reflection surface when the size of the end surface of the core of the optical transmission member is smaller than the size of the light-emitting surface of the light-emitting element; and disposing the optical receptacle main body on the substrate of the photoelectric conversion device.

### Advantageous Effects of Invention

According to the present invention, it is possible to provide an optical receptacle and an optical module that can maintain a high light coupling efficiency even in the case where the optical transmission member with a large core end surface is used.

### BRIEF DESCRIPTION OF DRAWINGS

FIG. 1 is a sectional view of an optical module according to Embodiment 1 of the present invention;

FIGS. 2A to 2D illustrate a configuration of an optical receptacle according to Embodiment 1;

FIG. 3 is a diagram for describing installation of a light-emitting element with respect to an optical transmission member and installation of a light-receiving element with respect to the optical transmission member;

FIGS. 4A to 4C are sectional views of an optical module according to a modification of Embodiment 1;

FIGS. 5A and 5B are sectional views of an optical module according to a modification of Embodiment 1; and

FIG. 6 is a sectional view of an optical module according to Embodiment 2 of the present invention.

### DESCRIPTION OF EMBODIMENTS

An optical module according to an embodiment of the present invention is elaborated below with reference to the accompanying drawings.

### Embodiment 1

Configuration of Optical Module

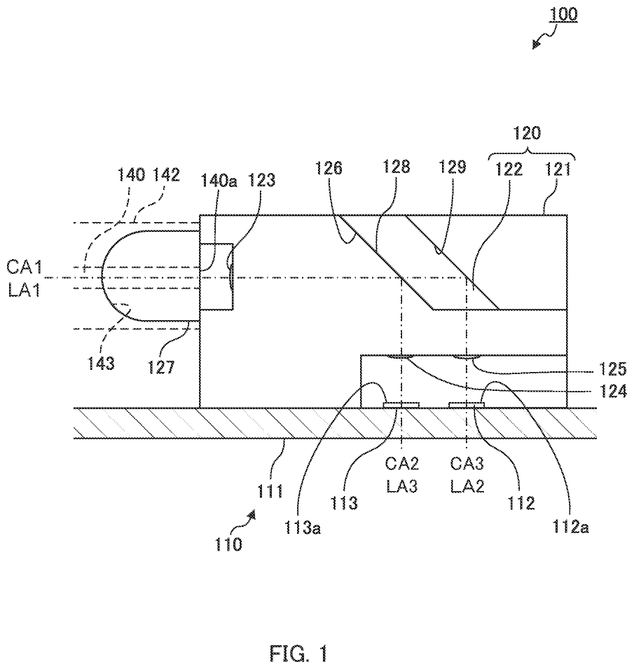

FIG. 1 is a sectional view of optical module 100 according to Embodiment 1 of the present invention. In FIG. 1, optical transmission member 140 and ferrule 142 are indicated by broken lines. In FIG. 1, the hatching of optical receptacle main body 121 and filter 122 is omitted for the sake of illustration of the central axis of the optical surface and the light axis of light.

As illustrated in FIG. 1, optical module 100 includes substrate-mounted photoelectric conversion device 110 and optical receptacle 120. Optical module 100 is used with optical transmission member 140 coupled (hereinafter referred to also as “connected”) to optical receptacle 120. Optical module 100 according to the present embodiment can be used for single core bidirectional communication. In this case, optical module 100 detects light (reception light) of a first wavelength emitted from end surface 140a of the core of optical transmission member 140, and emits light (transmission light) of a second wavelength different from the first wavelength to end surface 140a of the core of optical transmission member 140.

Photoelectric conversion device 110 includes substrate 111, light-emitting element 112 and light-receiving element 113.

Substrate 111 supports light-emitting element 112 and light-receiving element 113 and supports optical receptacle 120. Substrate 111 is, for example, a glass composite substrate, a glass epoxy substrate, a flexible substrate or the like. Light-emitting element 112 and light-receiving element 113 are disposed on substrate 111.

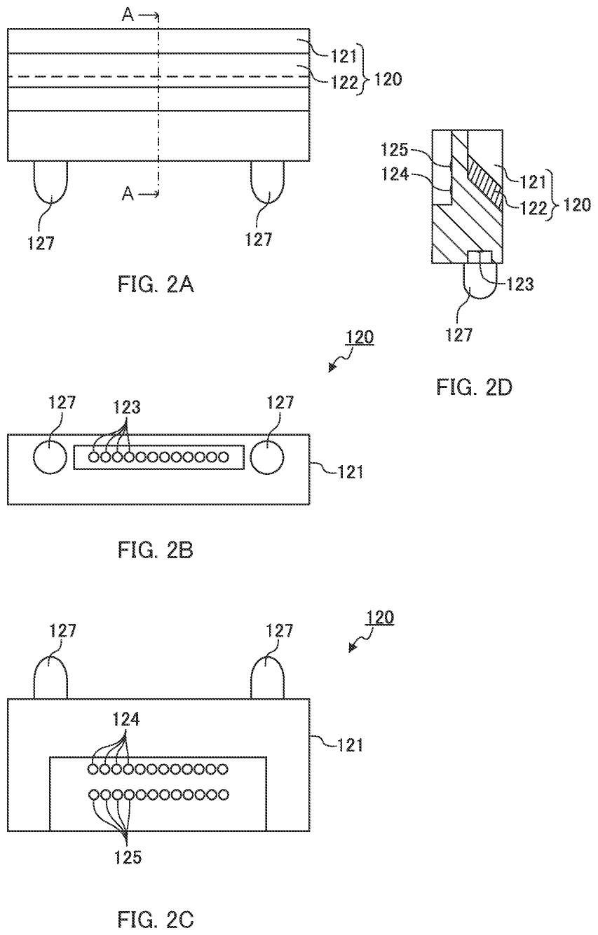

Light-emitting element 112 is disposed on substrate 111, and emits light of the second wavelength. The second wavelength is, for example, 800 to 1000 nm, or 1200 to 1600 nm but is not limited as long as it is different from the first wavelength and single core bidirectional communication can be appropriately performed. The light-emitting element is, for example, a light-emitting diode, or a vertical cavity surface emitting laser (VCSEL). The number of light-emitting elements 112 is not limited. In the present embodiment, the number of light-emitting element 112 is 12 (see FIG. 2). In addition, in the present embodiment, the size of end surface 140a of the core of optical transmission member 140 is greater than the size of light-emitting surface 112a of light-emitting element 112.

Light-receiving element 113 receives the light of the first wavelength emitted from end surface 140a of the core of optical transmission member 140. Light-receiving element 113 is, for example, a photodetector. The number of light-receiving elements 113 is not limited, and is selected in accordance with the configuration of optical receptacle 120. In the present embodiment, the number of light-receiving elements 113 is 12 (see FIG. 2). In addition, in the present embodiment, in accordance with the configuration in which the size of end surface 140a of the core of optical transmission member 140 is greater than the size of light-emitting surface 112a of light-emitting element 112 (as described later), light-receiving element 113 is disposed on optical transmission member 140 side than light-emitting element 112.

Optical receptacle 120 is disposed on substrate 111 of photoelectric conversion device 110. When optical receptacle 120 is disposed between photoelectric conversion device 110 and optical transmission member 140, optical receptacle 120 optically couples end surface 140a of the core of optical transmission member 140, light-emitting surface 112a of light-emitting element 112 and light-receiving surface 113a of light-receiving element 113. In the present embodiment, optical receptacle 120 optically couples end surfaces 140a of the cores of twelve optical transmission members 140, light-emitting surfaces 112a of twelve light-emitting elements 112 and light-receiving surfaces 113a of twelve light-receiving elements 113. The configuration of optical receptacle 120 is separately elaborated later.

The type of optical transmission member 140 is not limited. Examples of the type of optical transmission member 140 include optical fibers and light waveguides. In the present embodiment, optical transmission member 140 is an optical fiber. The optical fiber may be of a single mode type, or a multiple mode type. The first wavelength of light emitted from (reception light) end surface 140a of the core of optical transmission member 140 is, for example, 800 to 1000 nm, or 1200 to 1600 nm, but is not limited as long as it is different from the second wavelength and single core bidirectional communication can be appropriately performed. The number of optical transmission members 140 is not limited, and is selected in accordance with the configuration of optical receptacle 120. In the present embodiment, the number of optical transmission members 140 is 12 (see FIG. 2). In addition, in the present embodiment, optical transmission member 140 is connected to optical receptacle 120 through ferrule 142.

### Configuration of Optical Receptacle

FIGS. 2A to 2D illustrate a configuration of optical receptacle 120. FIG. 2A is a plan view of optical receptacle 120, FIG. 2B is a front view, FIG. 2C is a bottom view, and FIG. 2D is a sectional view taken along line A-A of FIG. 2A.

Optical receptacle 120 is optically transparent, emits the light (reception light) of the first wavelength emitted from end surface 140a of the core of optical transmission member 140 toward light-receiving surface 113a of light-receiving element 113, and emits the light (transmission light) of the second wavelength emitted from light-emitting surface 112a of light-emitting element 112 toward end surface 140a of the core of optical transmission member 140. As illustrated in FIGS. 2A to 2D, optical receptacle 120 includes optical receptacle main body 121 and filter 122.

Optical receptacle main body 121 includes first optical surface 123, second optical surface 124, third optical surface 125, and reflection surface 126. In the present embodiment, twelve first optical surfaces 123, twelve second optical surfaces 124, and twelve third optical surfaces 125 are provided. In the present embodiment, optical receptacle main body 121 further includes positioning part 127 for positioning optical transmission member 140.

Optical receptacle main body 121 is formed using a material that is optically transparent to light of wavelengths used in optical communications. Examples of such a material include transparent resins such as polyetherimide (PEI) and cyclic olefin resin. In addition, optical receptacle main body 121 is manufactured by injection molding, for example.

First optical surface 123 is an optical surface that allows, to enter optical receptacle main body 121, the light of the first wavelength emitted from end surface 140a of the core of optical transmission member 140, and emits, toward end surface 140a of the core of optical transmission member 140, the light having travelled inside optical receptacle main body 121. The shape of first optical surface 123 is not limited. First optical surface 123 may be a convex lens surface protruding toward optical transmission member 140, a concave lens surface recessed with respect to optical transmission member 140, or a flat surface. In the present embodiment, first optical surface 123 is a convex lens surface protruding toward optical transmission member 140. The shape in plan view of first optical surface 123 is not limited. The shape in plan view of first optical surface 123 may be a circular shape or a polygonal shape. In the present embodiment, the shape in plan view of first optical surface 123 is a circular shape.

First central axis CA1 of first optical surface 123 may or may not coincide with light axis LA 1 of the light of the first wavelength emitted from end surface 140a of the core of optical transmission member 140. That is, first central axis CA1 of first optical surface 123 may or may not coincide with the central axis (light axis LA 1) of end surface 140a of the core of optical transmission member 140. In the present embodiment, first central axis CA1 of first optical surface 123 coincides with the central axis (light axis LA 1) of end surface 140a of the core of optical transmission member 140 (see FIG. 1).

Second optical surface 124 is an optical surface disposed on first optical surface 123 side than third optical surface 125 and disposed facing light-emitting element 112 or light-receiving element 113. In the present embodiment, second optical surface 124 faces light-receiving element 113, and emits, toward light-receiving element 113, the light of the first wavelength having travelled inside optical receptacle main body 121. The shape of second optical surface 124 is not limited. Second optical surface 124 may be a convex lens surface protruding toward light-receiving element 113, a concave lens surface recessed with respect to light-receiving element 113, or a flat surface. In the present embodiment, second optical surface 124 is a convex lens surface protruding toward light-receiving element 113. The shape in plan view of second optical surface 124 is not limited. The shape in plan view of second optical surface 124 may be a circular shape or a polygonal shape. In the present embodiment, the shape in plan view of second optical surface 124 is a circular shape.

Second central axis CA2 of second optical surface 124 may or may not coincide with light axis LA3 of light-receiving surface 113a of light-receiving element 113. In the present embodiment, second central axis CA2 of second optical surface 124 coincides with the central axis (light axis LA3) of light-receiving surface 113a of light-receiving element 113 (see FIG. 1).

Reflection surface 126 is an inclined surface formed on the top surface side in optical receptacle main body 121, and is disposed on an optical path between first optical surface 123 and second optical surface 124. Reflection surface 126 is configured to internally reflect, toward second optical surface 124, the light entered from first optical surface 123, and to internally reflect, toward first optical surface 123, the light entered from second optical surface 124. In the present embodiment, reflection surface 126 is a flat surface tilted toward first optical surface 123 as it goes from the bottom surface toward the top surface of optical receptacle 120. In the present embodiment, the inclination angle of reflection surface 126 is 45° with respect to light axis LA 1 of the light entered from first optical surface 123.

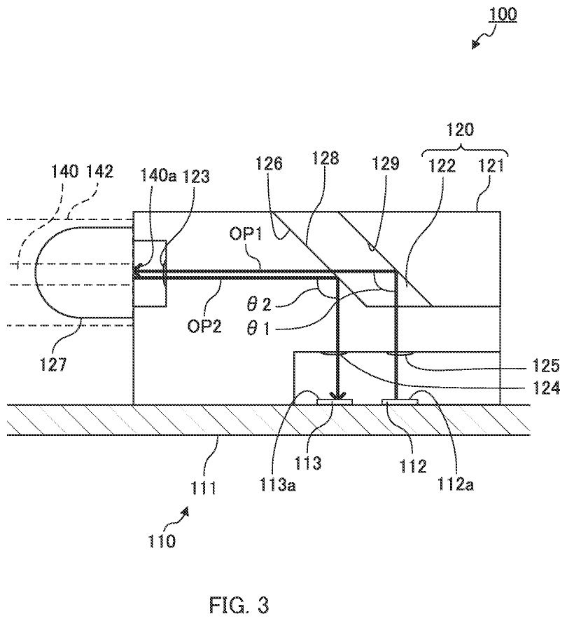

Note that as described later, first filter surface 128 or second filter surface 129 of filter 122 is in intimate contact with reflection surface 126. In the case where first filter surface 128 is in intimate contact with reflection surface 126, reflection surface 126 and first filter surface 128 reflect the light of the first wavelength and transmit the light of the second wavelength. In the case where second filter surface 129 is in intimate contact with reflection surface 126, reflection surface 126 and second filter surface 129 reflect the light of the second wavelength and transmit the light of the first wavelength. In the present embodiment, first filter surface 128 is in intimate contact with the reflection surface, and reflection surface 126 and first filter surface 128 reflect, toward second optical surface 124, the light of the first wavelength entered from first optical surface 123, and transmit, toward first optical surface 123, the light of the second wavelength entered from third optical surface 125 and reflected by second filter surface 129 (see FIG. 3).

Third optical surface 125 is an optical surface disposed at a position separated from first optical surface 123 than second optical surface 124 and disposed facing light-emitting element 112 or light-receiving element 113. In the present embodiment, third optical surface 125 faces light-emitting element 112 and allows incidence of the light of the second wavelength emitted from light-emitting element 112. The shape of third optical surface 125 is not limited. Third optical surface 125 may be a convex lens surface protruding toward light-emitting element 112, a concave lens surface a recessed with respect to light-emitting element 112, or a flat surface. In the present embodiment, third optical surface 125 is a convex lens surface protruding toward light-emitting element 112. The shape in plan view of third optical surface 125 is not limited. The shape in plan view of third optical surface 125 may be a circular shape or a polygonal shape. In the present embodiment, the shape in plan view of third optical surface 125 is a circular shape.

Third central axis CA3 of third optical surface 125 may or may not coincide with light axis LA2 of the light of the second wavelength emitted from the light-emitting surface of light-emitting element 112. In the present embodiment, third central axis CA3 of third optical surface 125 coincides with the central axis (light axis LA2) of light-emitting surface 112a of light-emitting element 112 (see FIG. 1).

Positioning part 127 sets the position of end surface 140a of the core of optical transmission member 140 with respect to optical receptacle main body 121. The configuration of positioning part 127 is not limited as long as the above-mentioned function can be ensured. In the present embodiment, positioning part 127 is a protrusion with a substantially columnar shape. By fitting positioning hole 143 formed in ferrule 142 to positioning part 127, end surface 140a of the core of optical transmission member 140 is positioned with respect to optical receptacle main body 121.

Filter 122 is disposed on reflection surface 126 at a location on the optical path between first optical surface 123 and second optical surface 124 and on the optical path between first optical surface 123 and third optical surface 125.

Filter 122 includes first filter surface 128 disposed at one surface and second filter surface 129 disposed at the other surface. First filter surface 128 reflects the light of the first wavelength and transmits the light of the second wavelength. On the other hand, second filter surface 129 reflects the light of the second wavelength and transmits the light of the first wavelength. The shape of each of first filter surface 128 and second filter surface 129 is a shape complementary to reflection surface 126. In the present embodiment, first filter surface 128 and second filter surface 129 are flat surfaces. First filter surface 128 and second filter surface 129 may or may not be disposed in parallel. In the present embodiment, the cross-sectional shape of the filter 122 is a parallelogram, and first filter surface 128 and second filter surface 129 are disposed in parallel.

Filter 122 is disposed on optical receptacle main body 121 such that first filter surface 128 or second filter surface 129 is in intimate contact with reflection surface 126. In the case where first filter surface 128 is in intimate contact with reflection surface 126, reflection surface 126 and first filter surface 128 reflect the light of the first wavelength and transmit the light of the second wavelength. In the case where second filter surface 129 is in intimate contact with reflection surface 126, reflection surface 126 and second filter surface 129 reflect the light of the second wavelength and transmit the light of the first wavelength.

In the present embodiment, first filter surface 128 is in intimate contact with reflection surface 126, and reflection surface 126 and first filter surface 128 are disposed at a location on the intersection of central axis CA1 of first optical surface 123 and central axis CA2 of second optical surface 124. In addition, second filter surface 129 is disposed at a location on the intersection of central axis CA1 of first optical surface 123 and central axis CA3 of third optical surface 125. Reflection surface 126 and first filter surface 128 reflect, toward second optical surface 124, the light of the first wavelength entered from first optical surface 123, and transmit, toward first optical surface 123, the light of the second wavelength entered from third optical surface 125 and reflected by second filter surface 129 (see FIG. 3). Second filter surface 129 reflects, toward first optical surface 123, the light of the second wavelength entered from third optical surface 125.

The configuration of filter 122 is not limited as long as the above-mentioned function can be ensured. For example, filter 122 is obtained by forming a coating (e.g., a semiconductor multi-layer film) that reflects the light of the first wavelength and transmits the light of the second wavelength at one surface of a substrate made of resin or glass, and forming a coating (e.g., a semiconductor multi-layer film) that reflects the light of the second wavelength and transmits the light of the first wavelength at the other surface. Preferably, the refractive index of the substrate is a refractive index close to, or more preferably the same as, the refractive index of the material (e.g., resin) of optical receptacle main body 121, while the refractive index of the substrate is not limited.

In the present embodiment, the light of the second wavelength emitted from light-emitting surface 112a of light-emitting element 112 enters optical receptacle main body 121 from third optical surface 125. The light entered from third optical surface 125 is transmitted through the interface between optical receptacle main body 121 and filter 122, and reflected by second filter surface 129 of filter 122 toward first optical surface 123. The light reflected by second filter surface 129 is transmitted through first filter surface 128 and reflection surface 126, and emitted from first optical surface 123 toward end surface 140a of the core of optical transmission member 140. In this manner, the light of the second wavelength emitted from light-emitting element 112 reaches optical transmission member 140 through third optical surface 125, second filter surface 129, and first optical surface 123 (see FIG. 3).

On the other hand, the light of the first wavelength emitted from end surface 140a of the core of optical transmission member 140 enters optical receptacle main body 121 from first optical surface 123, and reflected by reflection surface 126 (and first filter surface 128) toward second optical surface 124. The light reflected by reflection surface 126 is emitted from second optical surface 124 toward light-receiving surface 113a of light-receiving element 113. In this manner, the light of the first wavelength emitted from optical transmission member 140 reaches light-receiving element 113 through first optical surface 123, reflection surface 126 (first filter surface 128) and second optical surface 124 (see FIG. 3).

Now, the installation of light-emitting element 112 with respect to optical transmission member 140 and the installation of light-receiving element 113 with respect to optical transmission member 140 are described. FIG. 3 is a diagram for describing the installation of light-emitting element 112 with respect to optical transmission member 140 and the installation of light-receiving element 113 with respect to optical transmission member 140. In FIG. 3, the hatching of optical receptacle main body 121 and filter 122 is omitted for the sake of illustration of optical paths.

As illustrated in FIG. 3, the optical path between light-emitting surface 112a of light-emitting element 112 and end surface 140a of the core of optical transmission member 140 is referred to as first optical path OP1, and the optical path between end surface 140a of the core of optical transmission member 140 and light-receiving surface 113a of light-receiving element 113 is referred to as second optical path OP2.

In the case where the light emitted from the emission surface (e.g., end surface 140a of the core of optical transmission member 140 or light-emitting surface 112a of light-emitting element 112) is guided by optical receptacle 120 to the light-receiving surface (e.g., light-receiving surface 113a of light-receiving element 113 or end surface 140a of the core of optical transmission member 140), the light coupling efficiency between the emission surface and the light-receiving surface tends to decrease as the size of the emission surface increases. In addition, the light coupling efficiency tends to decrease as the length of the optical path increases. In view of this, in the present embodiment, the positions of light-emitting element 112 and light-receiving element 113 and the installation of filter 122 are set such that the optical path of the light emitted from a larger emission surface is the shorter optical path by comparing the size of light-emitting surface 112a of light-emitting element 112 and the size of end surface 140a of the core of optical transmission member 140. In the present embodiment, as described above, the size of end surface 140a of the core of optical transmission member 140 is equal to or greater than the size of light-emitting surface 112a of light-emitting element 112. Accordingly, light-receiving element 113 is disposed facing second optical surface 124 such that second optical path OP2 is shorter than first optical path OP1. In this case, the light emitted from optical transmission member 140 reaches light-receiving element 113 through second optical path OP2. Here, second optical path OP2 is shorter than first optical path OP1, and thus the light coupling efficiency for light-receiving element 113 can be maintained even in the case where end surface 140a of the core of optical transmission member 140 is large. Note that in the case where the size of end surface 140a of the core of optical transmission member 140 is smaller than the size of light-emitting surface 112a of light-emitting element 112, it is preferable that light-emitting element 112 is disposed facing second optical surface 124 (see Embodiment 2).

### Manufacturing Method of Optical Module

Next, a manufacturing method of the above-described optical module 100 is described. The manufacturing method of optical module 100 includes a step of disposing filter 122 on optical receptacle main body 121, and a step of disposing optical receptacle main body 121 on substrate 111 of photoelectric conversion device 110. The order of these steps is not limited.

In the step of disposing filter 122 on optical receptacle main body 121, which of first filter surface 128 and second filter surface 129 of filter 122 to be put in intimate contact with reflection surface 126 of optical receptacle main body 121 is determined by comparing the size of end surface 140a of the core of optical transmission member 140 and the size of light-emitting surface 112a of light-emitting element 112. To be more specific, in the case where the size of end surface 140a of the core of optical transmission member 140 is equal to or greater than the size of light-emitting surface 112a of light-emitting element 112, first filter surface 128 is put in intimate contact with reflection surface 126. On the other hand, in the case where the size of end surface 140a of the core of optical transmission member 140 is smaller than the size of light-emitting surface 112a of light-emitting element 112, second filter surface 129 is put in intimate contact with reflection surface 126.

In addition, optical receptacle main body 121 is disposed on substrate 111 of photoelectric conversion device 110 where light-emitting element 112 and light-receiving element 113 are disposed.

### Effect

As described above, in optical module 100 according to the present embodiment, the optical path of transmission light and the optical path of reception light can be changed in such a manner that by comparing the size of end surface 140a of the core of optical transmission member 140 and the size of light-emitting surface 112a of light-emitting element 112, the optical path of the light emitted from the larger surface is shorter. In this manner, even in the case where optical transmission member 140 with a large core end surface 140a is used, a high light coupling efficiency can be maintained.

In addition, in optical module 100 according to the present embodiment, the optical path of the reception light can be shortened in each of two optical modules 100 disposed at both ends of optical transmission member 140 by reversing the installation of first filter surface 128 and second filter surface 129 of filter 122. Further, in optical receptacle 120 according to the present embodiment, reflection surface 126 can serve a function even without filter 122, and thus optical receptacle main body 121 alone can function as an optical receptacle of single direction communication without using filter 122.

### Modification

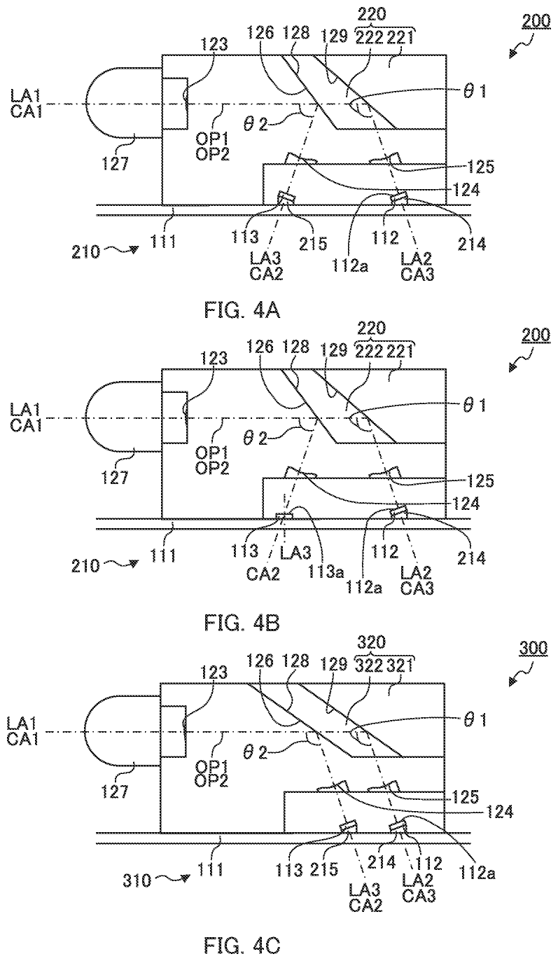

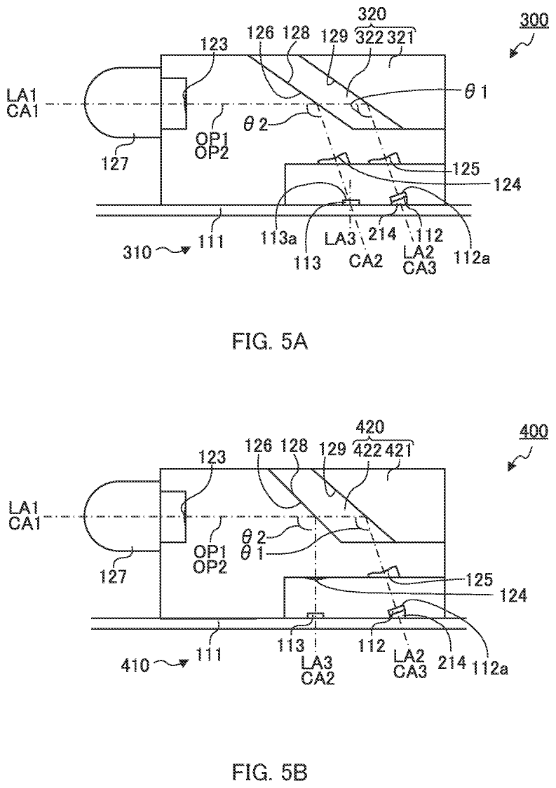

Next, optical modules 200, 300 and 400 according to modifications of Embodiment 1 are described. FIGS. 4A to 5B are sectional views of optical modules 200, 300 and 400 according to modifications of Embodiment 1. FIG. 4A is a sectional view of optical module 200 according to modification 1, FIG. 4B is a sectional view of optical module 300 according to another modification 1, and FIG. 4C is a sectional view of optical module 300 according to modification 2. FIG. 5A is a sectional view of optical module 300 according to another modification 2, and FIG. 5B is a sectional view of optical module 400 according to another modification 3. In FIGS. 4A to 5B, hatching is omitted for the sake of illustration of optical paths.

As illustrated in FIG. 4A, optical module 200 according to modification 1 includes photoelectric conversion device 210 and optical receptacle 220. Optical receptacle 220 includes optical receptacle main body 221 and filter 222.

Photoelectric conversion device 210 includes substrate 111, light-emitting element 112 and light-receiving element 113. Light-emitting element 112 is disposed on first seat 214 disposed on substrate 111 with light axis LA2 of light-emitting element 112 tilted with respect to the normal of substrate 111. Light-receiving element 113 is disposed on second seat 215 disposed on substrate 111 with light axis LA3 of light-receiving element 113 tilted with respect to the normal of substrate 111. Light axis LA2 of light-emitting element 112 is tilted toward optical transmission member 140 as it goes away from substrate 111. Light axis LA3 of light-receiving element 113 is tilted toward the side opposite to optical transmission member 140 as it goes away from substrate 111.

Second optical surface 124 of optical receptacle main body 221 is disposed such that central axis CA2 of second optical surface 124 is tilted with respect to the normal of substrate 111. Central axis CA2 of second optical surface 124 is tilted to the side opposite to optical transmission member 140 as it goes from the bottom surface toward the top surface of optical receptacle main body 221. In the example illustrated in FIG. 4A, central axis CA2 of second optical surface 124 coincides with light axis LA3 of light-receiving element 113. Note that as illustrated in FIG. 4B, it suffices that light-receiving element 113 is disposed such that light emitted from second optical surface 124 can be received, and, for example, light-receiving surface 113a of light-receiving element 113 may be disposed in parallel to substrate 111.

Third optical surface 125 is disposed with central axis CA3 of third optical surface 125 tilted with respect to the normal of substrate 111. Central axis CA3 of third optical surface 125 is tilted toward optical transmission member 140 as it goes from the bottom surface toward the top surface of optical receptacle main body 221. In the example illustrated in FIG. 4A, central axis CA3 of third optical surface 125 coincides with light axis LA2 of light-emitting element 112.

Reflection surface 126 is disposed at a location on the intersection of central axis CA1 of first optical surface 123 and central axis CA2 of second optical surface 124, and is tilted such that the light entered from first optical surface 123 is internally reflected toward second optical surface 124 and the light entered from second optical surface 124 is internally reflected toward first optical surface 123. The inclination angle of reflection surface 126 with respect to substrate 111 in optical receptacle 220 according to modification 1 (FIG. 4A) is greater than the inclination angle (45°) of reflection surface 126 with respect to substrate 111 in optical receptacle 120 according to embodiment 1 (FIG. 1).

Filter 222 includes first filter surface 128 and second filter surface 129. Filter 222 is disposed such that first filter surface 128 is in intimate contact with reflection surface 126. In the present modification, filter 222 has a trapezoidal cross-sectional shape. A pair of surfaces corresponding to the legs of the trapezoid includes first filter surface 128, and the other surface includes second filter surface 129. First filter surface 128 and second filter surface 129 are not in parallel. Second filter surface 129 is disposed at a location on the intersection of central axis CA1 of first optical surface 123 and central axis CA3 of third optical surface 125 in the state where first filter surface 128 is in intimate contact with reflection surface 126, and is tilted such that the light entered from first optical surface 123 is internally reflected toward third optical surface 125 and the light entered from third optical surface 125 is internally reflected toward first optical surface 123. The inclination angle of second filter surface 129 with respect to substrate 111 in optical receptacle 220 according to modification 1 (FIG. 4A) is smaller than the inclination angle (45°) of second filter surface 129 with respect to substrate 111 in optical receptacle 120 according to embodiment 1 (FIG. 1).

In the present modification, angle θ1 between light axis LA2 of the light emitted from light-emitting surface 112a of light-emitting element 112 and entered from third optical surface 125 and the light reflected by second filter surface 129 is greater than 90°. In addition, angle θ2 between light axis LA 1 of the light entered from first optical surface 123 and the light reflected by reflection surface 126 is smaller than 90°.

Next, optical module 300 according to modification 2 is described. In the following description, differences from optical module 200 according to modification 1 are mainly described.

As illustrated in FIG. 4C, optical module 300 according to modification 2 includes photoelectric conversion device 310 and optical receptacle 320. Optical receptacle 320 includes optical receptacle main body 321 and filter 322.

Photoelectric conversion device 310 includes substrate 111, light-emitting element 112 and light-receiving element 113. Light-emitting element 112 is disposed on first seat 214 disposed on substrate 111 with light axis LA2 of light-emitting element 112 tilted with respect to the normal of substrate 111. Light-receiving element 113 is disposed on second seat 215 disposed on substrate 111 with light axis LA3 of light-receiving element 113 tilted with respect to the normal of substrate 111. Light axis LA2 of light-emitting element 112 is tilted toward optical transmission member 140 as it goes away from substrate 111. Light axis LA3 of light-receiving element 113 is also tilted toward optical transmission member 140 as it goes away from substrate 111.

Second optical surface 124 of optical receptacle main body 321 is disposed with central axis CA2 of second optical surface 124 tilted with respect to the normal of substrate 111. Central axis CA2 of second optical surface 124 is tilted toward optical transmission member 140 as it goes from the bottom surface toward the top surface of optical receptacle main body 321. In the example illustrated in FIG. 4B, central axis CA2 of second optical surface 124 coincides with light axis LA3 of light-receiving element 113. In addition, central axis CA2 of second optical surface 124 (light axis LA3 of light-receiving element 113) is in parallel to central axis CA3 of third optical surface 125 (light axis LA2 of light-emitting element 112). Note that as illustrated in FIG. 5A, it suffices that light-receiving element 113 is disposed such that the light emitted from second optical surface 124 can be received, and, for example, light-receiving surface 113a of light-receiving element 113 may be disposed in parallel to substrate 111.

Reflection surface 126 is disposed at a location on the intersection of central axis CA1 of first optical surface 123 and central axis CA2 of second optical surface 124, and is tilted such that the light entered from first optical surface 123 is internally reflected toward second optical surface 124 and the light entered from second optical surface 124 is internally reflected toward first optical surface 123. The inclination angle of reflection surface 126 with respect to substrate 111 in optical receptacle 320 according to modification 2 (FIG. 4C) is smaller than the inclination angle (45°) of reflection surface 126 with respect to substrate 111 in optical receptacle 120 according to embodiment 1 (FIG. 1).

Filter 322 includes first filter surface 128 and second filter surface 129. Filter 322 is disposed such that first filter surface 128 is in intimate contact with reflection surface 126. The cross-sectional shape of the filter 322 is a parallelogram, and first filter surface 128 and second filter surface 129 are disposed in parallel. Second filter surface 129 is disposed at a location on the intersection of central axis CA1 of first optical surface 123 and central axis CA3 of third optical surface 125 in the state where first filter surface 128 is in intimate contact with reflection surface 126, and is tilted such that the light entered from first optical surface 123 is internally reflected toward third optical surface 125 and the light entered from third optical surface 125 is internally reflected toward first optical surface 123. The inclination angle of second filter surface 129 with respect to substrate 111 in optical receptacle 320 according to modification 2 (FIG. 4C) is smaller than the inclination angle (45°) of second filter surface 129 with respect to substrate 111 in optical receptacle 120 according to embodiment 1 (FIG. 1).

In the present modification, angle θ1 between light axis LA2 of the light emitted from light-emitting surface 112a of light-emitting element 112 and entered from third optical surface 125 and the light reflected by second filter surface 129 is greater than 90°. In addition, angle θ2 between light axis LA 1 of the light entered from first optical surface 123 and the light reflected by reflection surface 126 is also greater than 90°.

Next, optical module 400 according to modification 3 is described. In the following description, differences from optical module 200 according to modification 1 are mainly described.

As illustrated in FIG. 5B, optical module 400 according to modification 3 includes photoelectric conversion device 410 and optical receptacle 420. Optical receptacle 420 includes optical receptacle main body 421 and filter 422.

Photoelectric conversion device 410 includes substrate 111, light-emitting element 112 and light-receiving element 113. Light-emitting element 112 is disposed on first seat 214 disposed on substrate 111 with light axis LA2 of light-emitting element 112 tilted with respect to the normal of substrate 111. Light axis LA2 of light-emitting element 112 is tilted toward optical transmission member 140 as it goes away from substrate 111. Light-receiving element 113 is disposed on substrate 111 such that light axis LA3 of light-receiving element 113 is parallel to the normal of substrate 111.

Second optical surface 124 of optical receptacle main body 421 is disposed such that central axis CA2 of second optical surface 124 is parallel to the normal of substrate 111. In the example illustrated in FIG. 5B, central axis CA2 of second optical surface 124 coincides with light axis LA3 of light-receiving element 113.

Reflection surface 126 is disposed at a location on the intersection of central axis CA1 of first optical surface 123 and central axis CA2 of second optical surface 124, and is tilted such that the light entered from first optical surface 123 is internally reflected toward second optical surface 124 and the light entered from second optical surface 124 is internally reflected toward first optical surface 123. The inclination angle of reflection surface 126 with respect to substrate 111 in optical receptacle 420 according to modification 3 (FIG. 5B) is the same as the inclination angle (45°) of reflection surface 126 with respect to substrate 111 in optical receptacle 120 according to embodiment 1 (FIG. 1).

Filter 422 includes first filter surface 128 and second filter surface 129. Filter 422 is disposed such that first filter surface 128 is in intimate contact with reflection surface 126. In the present modification, filter 422 has a trapezoidal cross-sectional shape. A pair of surfaces corresponding to the legs of the trapezoid includes first filter surface 128, and the other surface includes second filter surface 129. First filter surface 128 and second filter surface 129 are not in parallel. Second filter surface 129 is disposed at a location on the intersection of central axis CA1 of first optical surface 123 and central axis CA3 of third optical surface 125 in the state where first filter surface 128 is in intimate contact with reflection surface 126, and is tilted such that the light entered from first optical surface 123 is internally reflected toward third optical surface 125 and the light entered from third optical surface 125 is internally reflected toward first optical surface 123. The inclination angle of second filter surface 129 with respect to substrate 111 in optical receptacle 420 according to modification 3 (FIG. 5B) is smaller than the inclination angle (45°) of second filter surface 129 with respect to substrate 111 in optical receptacle 120 according to embodiment 1 (FIG. 1).

In the present modification, angle θ1 between light axis LA2 of the light emitted from light-emitting surface 112a of light-emitting element 112 and entered from third optical surface 125 and the light reflected by second filter surface 129 is greater than 90°. In addition, angle θ2 between light axis LA 1 of the light entered from first optical surface 123 and the light reflected by reflection surface 126 is 90°.

### Embodiment 2

In Embodiment 2, a case where the size of end surface 140a of the core of optical transmission member 140 is smaller than the size of light-emitting surface 112a of light-emitting element 112. In optical module 500 according to Embodiment 2, the size of end surface 140a of the core of optical transmission member 140 is smaller than the size of light-emitting surface 112a of light-emitting element 112, and accordingly optical module 500 according to Embodiment 2 is different from optical module 100 according to Embodiment 1 in the installation of light-emitting element 112 and the front and rear of light-receiving element 113 and filter 122. In view of this, the components similar to optical module 100 according to Embodiment 1 are denoted with the same reference numerals and the description thereof will be omitted.

### Configuration of Optical Module

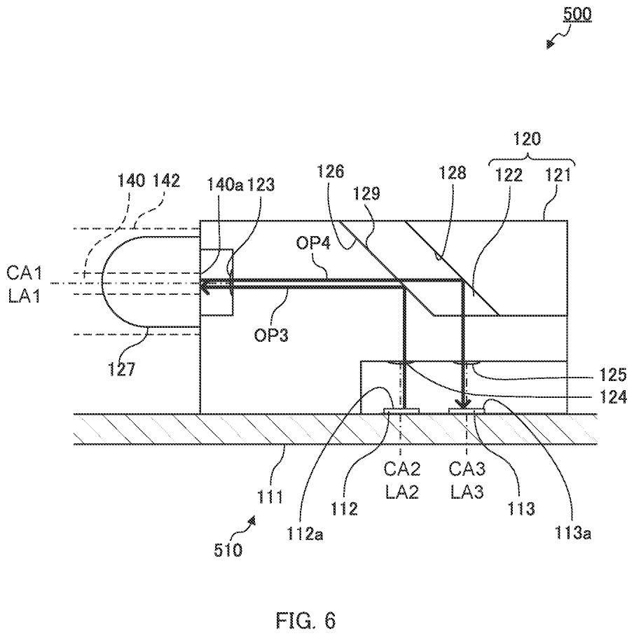

FIG. 6 is a sectional view of optical module 500 according to Embodiment 2 of the present invention. In FIG. 6, the hatching of optical receptacle main body 121 and filter 122 is omitted for the sake of illustration of optical paths.

As illustrated in FIG. 6, optical module 500 includes photoelectric conversion device 510 and optical receptacle 120. As described above, in the present embodiment, the size of end surface 140a of the core of optical transmission member 140 is smaller than the size of light-emitting surface 112a of light-emitting element 112.

Photoelectric conversion device 510 includes substrate 111, light-emitting element 112 and light-receiving element 113. In the present embodiment, light-emitting element 112 is disposed facing second optical surface 124, and light-receiving element 113 is disposed facing third optical surface 125.

Optical receptacle 120 includes optical receptacle main body 121 and filter 122. Optical receptacle main body 121 has the same structure as optical receptacle main body 121 in Embodiment 1, but is different from optical receptacle main body 121 in Embodiment 1 in the functions of second optical surface 124 and third optical surface 125.

In the present embodiment, second optical surface 124 faces light-emitting element 112, and allows, to enter optical receptacle main body 121, the light of the second wavelength emitted from light-emitting surface 112a of light-emitting element 112. Second central axis CA2 of second optical surface 124 may or may not coincide with light axis LA2 of the light of the second wavelength emitted from the light-emitting surface of light-emitting element 112. In the present embodiment, second central axis CA2 of second optical surface 124 coincides with the central axis (light axis LA2) of light-emitting surface 112a of light-emitting element 112.

In the present embodiment, third optical surface 125 faces light-receiving element 113, and emits, toward light-receiving surface 113a of light-receiving element 113, the light of the first wavelength travelled inside optical receptacle 120. Third central axis CA3 of third optical surface 125 may or may not coincide with light axis LA3 of light-receiving surface 113a of light-receiving element 113. In the present embodiment, third central axis CA3 of third optical surface 125 coincides with the central axis (light axis LA3) of light-receiving surface 113a of light-receiving element 113.

Filter 122 includes first filter surface 128 and second filter surface 129. In the present embodiment, filter 122 is disposed on optical receptacle main body 121 such that second filter surface 129 is in intimate contact with reflection surface 126. In the case where second filter surface 129 is in intimate contact with reflection surface 126, reflection surface 126 and second filter surface 129 reflect the light of the second wavelength and transmit the light of the first wavelength. In the present embodiment, the cross-sectional shape of the filter 122 is a parallelogram, and first filter surface 128 and second filter surface 129 are disposed in parallel.

In the present embodiment, second filter surface 129 is in intimate contact with reflection surface 126, and reflection surface 126 and second filter surface 129 are disposed at a location on the intersection of central axis CA1 of first optical surface 123 and central axis CA2 of second optical surface 124. In addition, first filter surface 128 is disposed at a location on the intersection of central axis CA1 of first optical surface 123 and central axis CA3 of third optical surface 125. Reflection surface 126 and second filter surface 129 reflect, toward first optical surface 123, the light of the second wavelength entered from second optical surface 124, and transmit, toward first filter surface 128, the light of the first wavelength entered from first optical surface 123. First filter surface 128 reflects, toward third optical surface 125, the light of the first wavelength transmitted through second filter surface 129.

In the present embodiment, the light of the first wavelength entered from first optical surface 123 is transmitted through reflection surface 126 and second filter surface 129. The light transmitted through reflection surface 126 and second filter surface 129 is reflected by first filter surface 128 toward third optical surface 125, and emitted from third optical surface 125 toward light-receiving surface 113a of light-receiving element 113. The light emitted from light-emitting surface 112a of light-emitting element 112 enters optical receptacle 120 from second optical surface 124. The light having entered optical receptacle 120 is reflected by reflection surface 126 (second filter surface 129) toward first optical surface 123, and emitted from first optical surface 123 toward end surface 140a of the core of optical transmission member 140.

Now, the installation of light-emitting element 112 with respect to optical transmission member 140 and the installation of light-receiving element 113 with respect to optical transmission member 140 are described. As illustrated in FIG. 5, the optical path between light-emitting surface 112a of light-emitting element 112 and end surface 140a of the core of optical transmission member 140 is referred to as third optical path OP3, and the optical path between end surface 140a of the core of optical transmission member 140 and light-receiving surface 113a of light-receiving element 113 is referred to as fourth optical path OP4. In the present embodiment, as described above, the size of end surface 140a of the core of optical transmission member 140 is smaller than the size of light-emitting surface 112a of light-emitting element 112. As such, light-emitting element 112 is disposed facing second optical surface 124 such that third optical path OP3 is shorter than fourth optical path OP4. The light emitted from core end surface 140a of optical transmission member 140 reaches light-receiving element 113 through fourth optical path OP4. On the other hand, the light emitted from light-emitting surface 112a of light-emitting element 112 reaches end surface 140a of the core of optical transmission member 140 through third optical path OP3. Third optical path OP3 is shorter than fourth optical path OP4, and thus the light coupling efficiency for end surface 140a of the core of optical transmission member 140 can be maintained even in the case where light-emitting surface 112a of light-emitting element 112 is larger than end surface 140a of optical transmission member 140.

### Effect

In this manner, optical module 500 according to the present embodiment has an effect similar to that of optical module 100 according to Embodiment 1.

This application is entitled to and claims the benefit of Japanese Patent Application No. 2019-059240 filed on Mar. 26, 2019, the disclosure each of which including the specification, drawings and abstract is incorporated herein by reference in its entirety.

### INDUSTRIAL APPLICABILITY

The optical receptacle and the optical module according to the embodiments of the present invention are suitable for optical communications using optical transmission members.

### REFERENCE SIGNS LIST

100, 200, 300, 400, 500 Optical module
110, 210, 310, 410, 510 Photoelectric conversion device
111 Substrate
112 Light-emitting element
112a Light-emitting surface
113 Light-receiving element
113a Light-receiving surface
120, 220, 320, 420 Optical receptacle
121, 221, 321, 421 Optical receptacle main body
122, 222, 322, 422 Filter
123 First optical surface
124 Second optical surface
125 Third optical surface
126 Reflection surface
127 Positioning part
128 First filter surface
129 Second filter surface
140 Optical transmission member
140a End surface of core
142 Ferrule
143 Positioning hole
214 First seat
215 Second seat
CA1 Central axis of first optical surface
CA2 Central axis of second optical surface
CA3 Central axis of third optical surface
LA1 Light axis of end surface of optical transmission member (Light axis of light emitted from optical transmission member)
LA2 Light axis of light-emitting surface of light-emitting element (Light axis of light emitted from light-emitting element)
LA3 Light axis of light-receiving surface of light-receiving element

1. An optical receptacle configured to optically couple an optical transmission member, a light-emitting element and a light-receiving element when the optical receptacle is disposed between the optical transmission member and a photoelectric conversion device including the light-emitting element and the light-receiving element, the optical transmission member being configured to emit light of a first wavelength, the light-emitting element being configured to emit light of a second wavelength different from the first wavelength, the light-receiving element being configured to receive the light of the first wavelength, the optical receptacle comprising:
an optical receptacle main body; and
a filter disposed on the optical receptacle main body,
wherein the optical receptacle main body includes:
a first optical surface configured to allow incidence of the light of the first wavelength emitted from the optical transmission member, or emit, toward the optical transmission member, the light of the second wavelength having travelled inside the optical receptacle main body,
a second optical surface configured to emit, toward the light-receiving element, the light of the first wavelength having travelled inside the optical receptacle main body, or allow incidence of the light of the second wavelength emitted from the light-emitting element,
a third optical surface disposed at a position separated from the first optical surface than the second optical surface, and configured to emit, toward the light-receiving element, the light of the first wavelength having travelled inside the optical receptacle main body, or allow incidence of the light of the second wavelength emitted from the light-emitting element, and
a reflection surface disposed on an optical path between the first optical surface and the second optical surface, and configured to internally reflect, toward the first optical surface, the light of the second wavelength entered from the second optical surface, or internally reflect, toward the second optical surface, the light of the first wavelength entered from the first optical surface,
wherein the filter includes:
a first filter surface disposed at one surface and configured to reflect the light of the first wavelength and transmit the light of the second wavelength, and
a second filter surface disposed at another surface and configured to reflect the light of the second wavelength and transmit the light of the first wavelength,
wherein when the second optical surface is used to emit the light of the first wavelength toward the light-receiving element, or when the third optical surface is used to allow incidence of the light of the second wavelength:
the filter is disposed on the optical receptacle main body such that the first filter surface is in intimate contact with the reflection surface,
the second filter surface reflects, toward the first optical surface, the light of the second wavelength entered from the third optical surface, and
the reflection surface and the first filter surface reflect, toward the second optical surface, the light of the first wavelength entered from the first optical surface, or transmit, toward the first optical surface, the light of the second wavelength reflected by the second filter surface, and
wherein when the second optical surface is used to allow incidence of the light of the second wavelength, or when the third optical surface is used to emit, toward the light-receiving element, the light of the first wavelength:
the filter is disposed on the optical receptacle main body such that the second filter surface is in intimate contact with the reflection surface,
the reflection surface and the second filter surface reflect, toward the first optical surface, the light of the second wavelength entered from the second optical surface, or transmit, toward the first filter surface, the light of the first wavelength entered from the first optical surface, and
the first filter surface reflects, toward the third optical surface, the light of the first wavelength transmitted through the second filter surface.

2. The optical receptacle according to claim 1, wherein the first filter surface and the second filter surface are parallel to each other.

3. An optical module, comprising:
a photoelectric conversion device including a substrate, a light-emitting element disposed on the substrate and a light-receiving element disposed on the substrate; and
the optical receptacle according to claim 1.

4. The optical module according to claim 3,
wherein when a size of an end surface of a core of an optical transmission member used in combination with the optical module is equal to or greater than a size of a light-emitting surface of the light-emitting element:
the light-emitting element is disposed on the substrate to face the third optical surface,
the light-receiving element is disposed on the substrate to face the second optical surface, and
the filter is disposed on the optical receptacle main body such that the first filter surface is in intimate contact with the reflection surface, and
wherein when the size of the end surface of the core of the optical transmission member is smaller than the size of the light-emitting surface of the light-emitting element:
the light-emitting element is disposed on the substrate to face the second optical surface,
the light-receiving element is disposed on the substrate to face the third optical surface, and
the filter is disposed on the optical receptacle main body such that the second filter surface is in intimate contact with the reflection surface.

5. A method of manufacturing the optical module according to claim 4, the method comprising:
disposing the filter on the optical receptacle main body such that the first filter surface is in intimate contact with the reflection surface when the size of the end surface of the core of the optical transmission member is equal to or greater than the size of the light-emitting surface of the light-emitting element, or disposing the filter on the optical receptacle main body such that the second filter surface is in intimate contact with the reflection surface when the size of the end surface of the core of the optical transmission member is smaller than the size of the light-emitting surface of the light-emitting element; and
disposing the optical receptacle main body on the substrate of the photoelectric conversion device.

6. An optical module, comprising:
a photoelectric conversion device including a substrate, a light-emitting element disposed on the substrate and a light-receiving element disposed on the substrate; and
the optical receptacle according to claim 2.
